(19) United States
(12) Patent Application Publication
(10) Pub. No.: US 2006/0051970 A1
(43) Pub. Date: Mar. 9, 2006

(54) Method for forming porous film and porous film formed by the method

(75) Inventors: Nobuyuki Kawakami, Kobe-shi (JP); Takayuki Hirano, Kobe-shi (JP)

Correspondence Address: REED SMITH LLP, SUITE 1400, 3110 FAIRVIEW PARK DR., FALLS CHURCH, VA, 22032, US

(73) Assignee: Kabushiki Kaisha Kobe Seiko Sho

(21) Appl. No.: 11/219,872

(22) Filed: Sep. 7, 2005

(30) Foreign Application Priority Data
Sep. 7, 2004 (JP) 2004-259197
Jul. 8, 2005 (JP) 2005-199598

(51) Int. Cl. H01L 21/31

(52) U.S. Cl. 438/758

(57) ABSTRACT

A method for forming a porous film includes the precursor film forming step of forming a precursor film containing a mixture of a skeleton material and a pore-forming material, the decomposition step of decomposing the pore-forming material in the precursor film by oxidation in an oxidizing atmosphere, and the extraction step of extracting the decomposed pore-forming material with a supercritical fluid. The pore-forming material may be a surfactant. The surfactant may be decomposed by oxidation in an oxidizing atmosphere at 100 to 150° C.

### BACKGROUND OF THE INVENTION

1. Field of the Invention

The present invention relates to a method for forming a porous film, not including a firing step. In particular, the method can be suitably applied to the formation of a porous film having a low dielectric constant which is suitably used as a dielectric layer of a high-frequency circuit or an insulating interlayer of a semiconductor integrated circuit (for example, LSI).

2. Description of the Related Art

Spin-on-glass (SOG) films, which are insulating coating films mainly containing SiO₂, are widely used as insulating interlayers of, for example, semiconductor devices. Low dielectric constant insulating interlayers containing an organic substance have also been developed with the progress of semiconductor integration. However, still higher semiconductor integration and multilayering have been increasingly desired. Accordingly, an insulating interlayer having a still lower dielectric constant is desired and whose relative dielectric constant is as low as 2 or less.

In order to achieve a relative dielectric constant of 2 or less, it is necessary to reduce the density of the layer. Accordingly, a porous material is used for such a layer. Unfortunately, as the density is reduced, the mechanical strength of the porous material is, in general, significantly degraded. This is because pores formed to reduce the density are nonuniformly dispersed in the material. In order to maintain the strength even if the density is reduced, it is advantageous to realize a highly regular or periodic structure, such as honeycomb.

In order to produce a porous material having a regular or periodic structure, U.S. Pat. No. 5,958,577 has disclosed a method in which alkoxysilane, water, and a surfactant are blended and allowed to react to prepare a silica/surfactant composite, followed by aging, drying, and firing.

For the formation of a porous thin film having a periodic structure, European Patent Application Publication No. 739856 has disclosed a method in which tetraalkoxysilane is hydrolyzed in the presence of an acid and subsequently mixed with a surfactant. The resulting solution is applied onto a base material and dried to form a silica-surfactant nanocomposite, followed by firing.

These methods disadvantageously require the step of firing the surfactant, which is a pore-forming material for the porous structure, at a high temperature of at least 500° C. The methods cannot therefore be applied to the formation of insulating interlayers of semiconductor devices.

U. S. Pat. No. 6,423,770 has disclosed a method capable of forming a porous material at low temperature. In this method, a non-silicate constituent is extracted from a material composed of a silicate region and non-silicate regions by solvent exchange or fluid exchange to produce a porous silicate. For the extraction, the method also uses a supercritical fluid. Since processes using a supercritical fluid do not allow the occurrence of capillary force, as broadly known, such a process makes the deformation of materials from which a solvent is extracted very small. An example in U.S. Pat. No. 6,423,770 uses a supercritical fluid composed of isopropyl alcohol alone.

U.S. patent application Publication No. 2003/0008155 has disclosed, but not including concrete examples, a supercritical medium containing a solvent compatible with the object to be extracted.

EP Patent Application Publication No. 1508913 has disclosed that a coating made of an inorganic composition containing a nanoscopic particulate template, which serves to form pores, is made porous by extracting the template from the coating with a supercritical fluid.

In the foregoing U.S. Pat. No. 6,423,770, however, it is difficult to remove all the non-silicate regions. The non-silicate regions before turning porous contain a surfactant and many types of material, such as a photoinitiator and an organic substance, and the supercritical fluid, which can generally be a good solvent, is not necessarily miscible or compatible with all those materials. In the foregoing U.S. patent application Publication No. 2003/0008155, if a targeted constituent to be extracted has a molecular weight of more than a certain level, it cannot be dissolved even if another solvent is added. The capability of solvent in extracting a targeted constituent, that is, compatibility, generally depends on the molecular weight of the targeted constituent. In the foregoing EP Patent Application Publication 1508913 as well, if the molecular weight of the template is increased to some extent, the template becomes difficult to dissolve in the supercritical fluid.

In the known methods for porous structures, using a supercritical fluid for removing the pore-forming material, it is difficult to form a high-quality porous film having a low relative dielectric constant unless the pore-forming material is inherently compatible with the supercritical fluid. Therefore there is a limit on selecting the constituent of the pore-forming material to be extracted with the supercritical fluid, and accordingly the pore size and skeleton structure of the resulting porous film is limited disadvantageously.

### SUMMARY OF THE INVENTION

In view of the above disadvantages in forming porous films, the present invention provides a method for forming a porous film in which various types of pore-forming material can be used irrespective of its compatibility with the extractant or supercritical fluid, and thus in which the pore size and skeleton structure of the porous film can be selected from wide ranges of options. The present invention also provides a porous film formed by the method.

The method for forming a porous film of the present invention includes the precursor film forming step of forming a precursor film containing a mixture of a skeleton material for forming a skeleton of the porous film and a pore-forming material for forming pores. The decomposition step is also performed in which the pore-forming material is decomposed by oxidation in an oxidizing atmosphere. In the extraction step, the decomposed pore-forming material is extracted with a supercritical fluid.

In this method, after the precursor film is formed, the pore-forming material in the precursor film was decomposed into low-molecular-weight molecules by oxidation. The low-molecular-weight molecules have an enhanced compatibility with the supercritical fluid. In the extraction step using the supercritical fluid, the low-molecular-weight molecules are extracted with the supercritical fluid. In the precursor film forming step, therefore, various types of pore-forming material can be used without limitation on the molecular weight or structure of the pore-forming material. Accordingly, the pore size and the skeleton structure of the porous film can be selected from wide ranges of options. In addition, since the extraction step using the supercritical fluid extracts the pore-forming material decomposed into low-molecular-weight molecules, it can efficiently be performed, and thus high productivity can be achieved. Use of the supercritical fluid allows the extraction step to be performed at a low temperature. This is suitable for forming, for example, an insulating interlayer of a semiconductor device. Furthermore, the method of the present invention is advantageous in that if the pore-forming material is directly extracted with the supercritical fluid, changes of the microstructure can be reduced.

The pore-forming material may be an organic substance. Preferably, the organic substance is a surfactant. Since an appropriate concentration of surfactant forms micelles, the molecules of the pore-forming material can be placed in a regular manner, and thus a skeleton having a regular structure can be formed. Preferably, the surfactant is a nonionic surfactant. The nonionic surfactant has an ethylene oxide or propylene oxide structure, that is, the C—O bond, in its structure. Since this bond easily forms the C═O bond by oxidation, the nonionic surfactant can be more easily oxidized and decomposed than ionic surfactants, and thus exhibit high decomposition efficiency. The stability of the nonionic surfactant is slightly degraded after the formation of the precursor film, and the nonionic surfactant becomes liable to separate from the film. However, the nonionic surfactant is stabilized by oxidation decomposition. Consequently, the microstructure of the film can be stabilized and the resulting porous film has a high-quality microstructure.

In use of a surfactant as the pore-forming material, it is preferable that the decomposition step decompose the surfactant in an oxidizing atmosphere containing an oxidizing gas at a temperature of 100 to 150° C. These conditions make the oxidation decomposition of the surfactant easy, and prevent the surfactant from being excessively oxidized and decomposed and from separating from the precursor film, effectively. Consequently, the resulting porous film has a high-quality microstructure.

Preferably, the skeleton material is an inorganic substance, and particularly an inorganic substance mainly containing silica. Such an inorganic substance forms a highly insulating and stable skeleton for the porous film, and thus the resulting porous film has a low dielectric constant. Preferably, the supercritical fluid used in the extraction step mainly contains at least one of carbon dioxide and an alkyl alcohol.

In the method of the present invention, the pore-forming material is decomposed into low-molecular-weight molecules by oxidation in an oxidizing atmosphere, and is thus efficiently extracted. Consequently, high productivity can be achieved. In addition, the pore-forming material can be selected from a wide range of options, and accordingly the pore size and the skeleton structure of the porous film can be selected as required. In the method of the present invention, since the pore-forming material can be extracted at low temperatures, the method can be suitably applied to the formation of an insulating interlayer of, for example, a semiconductor device.

### BRIEF DESCRIPTION OF THE DRAWINGS

FIG. 1 is a graph showing the relationships between the wave number and the absorbance before and after supercritical extraction performed in an example; and

FIG. 2 is a graph showing the relationships between the wave number and the absorbance before and after heat treatment performed in an oxidizing atmosphere in an example.

### DESCRIPTION OF THE PREFERRED EMBODIMENTS

The method for forming a porous film according to preferred embodiments of the present invention includes the following three steps: (1) the precursor film forming step of forming a precursor film containing a skeleton material for forming a skeleton of the porous film and a pore-forming material for forming pores mixed with the skeleton material; (2) the decomposition step of decomposing the pore-forming material by oxidation; and (3) the extraction step of extracting the decomposed pore-forming material with a supercritical fluid.

In the precursor film forming step, the skeleton material, which will be described in detail later, and the pore-forming material are mixed together with water or water and alcohol with stirring to prepare a precursor solution containing the hydrolyzed skeleton material and the pore-forming material. The solution is applied onto the surface of a substrate by spin coating or roll coating, followed by drying. Thus, the precursor film containing a uniform mixture of the skeleton material and the pore-forming material is formed over the surface of the substrate. The precursor film undergoing the decomposition step and the extraction step is generally supported on the substrate.

The decomposition step decomposes the pore-forming material in an oxidizing atmosphere by oxidation, thereby reducing the molecular weight of the pore-forming material. For example, if a surfactant having a high molecular weight is used as the pore-forming material, the resulting pores have a large pore size depending on the molecular weight of the surfactant. It is however difficult to remove the surfactant or the pore-forming material with a supercritical fluid after the formation of the precursor film in which the skeleton material and the surfactant are uniformly mixed. The high-molecular-weight surfactant, which has a long-chain molecular structure, can easily be decomposed into low-molecular-weight molecules. The resulting surfactant having a low molecular weight can be easily reduced with a supercritical fluid. The molecular weight of the decomposed pore-forming material can be appropriately set according to the extraction capability of the supercritical fluid, which will be described later.

The molecular weight is generally determined by gel permeation chromatography (GPC). The GPC estimates the molecular weight of measuring objects by use of the phenomenon in which the permeation rate of a measuring object depends on its molecular weight. More specifically, the measuring object is dissolved in a solvent and the solution is allowed to penetrate a gel column. The molecular weight of the object is thus determined from the penetration rate at this point. Unfortunately, the GPC is not suitable in the present invention. The pore-forming material is decomposed in the decomposition step, and accordingly the chemical characteristics of the decomposed molecules are altered. While the penetration rate of the pore-forming material being a surfactant through a gel column depends on not only its molecular weight, but also interaction between the molecules and the gel, the hydrophilicity or hydrophobicity of the surfactant is changed by the oxidation decomposition, and thus the interaction between the surfactant molecules and the gel is changed. For example, if the interaction becomes strong, the penetration rate is reduced. The molecular weight of the surfactant or the pore-forming material cannot be estimated directly from the permeation rate through the gel column. It is therefore preferable that the molecular weight after oxidation decomposition be estimated by use of the infrared absorbances of the pore-forming material before and after the oxidation decomposition, as described in detail in the Example below.

The oxidizing atmosphere may be made of an oxidizing gas, such as O₂, O₃, N₂O, H₂O₂, HCl, HBr, Cl₂, BCl₃, or HNO₃, or may contain at least 0.1 vol %, preferably 1 vol % or more, of the oxidizing gas. For dilution of the oxidizing gas, an inert gas is used, such as nitrogen gas or Ar, He, or other rare gases. These oxidizing gases or the inert gases may be used singly or in combination. Among the oxidizing gases, H₂O₂, HCl, HBr, Cl₂, BCl₃, and HNO₃ are harmful if they are used at high temperatures. Therefore these gases are preferably diluted to a concentration of 20 vol % or less with an inert gas. If a surfactant acting as the pore-forming material is decomposed by oxidation, the oxidation decomposition is preferably performed at 100 to 150° C., more preferably 110 to 140° C., from the viewpoint of promoting the oxidation decomposition. A temperature of lower than 100° C. cannot promote the oxidation sufficiently. A temperature of higher than 150° C. results in excessive decomposition of the surfactant, and thus the surfactant separates from the film before the extraction step.

Since the oxidation decomposition results from the oxidation of the pore-forming material, this reaction can be controlled by varying the pressure of the oxidizing atmosphere or the time of the treatment, as well as the temperature of the oxidizing atmosphere. In view of industrial productivity, the oxidation decomposition is preferably performed under the following conditions.

The pressure of the oxidizing atmosphere is preferably in the range of about 0.1 Pa to 2 MPa. If the reaction is performed at a low pressure in the range, a more active oxidizing atmosphere is selected so as to promote the reaction because the concentration of the oxidizing gas is low. Specifically, the oxidizing atmosphere may be in plasma, or may contain highly active oxidizing constituent, such as oxygen radical or ozone. On the other hand, if the reaction is performed at a high pressure, the pressure is preferably set at 2 MPa or less from the viewpoint of preventing the separation of the surfactant from the film. The present inventors have found from experimental results that the separation notably occurs at a pressure of about more than 2 MPa. In order to promote the oxidation decomposition effectively, electromagnetic waves, such as electron beam, may be used in the oxidizing atmosphere.

The treatment time is appropriately set according to the thickness of the targeted porous film because the treatment time required depends on the thickness. Preferably, the treatment time in the decomposition step is about several tens of minutes to 100 minutes in view of the throughput of the treatment and the productivity.

The skeleton material for forming the skeleton of the porous structure is preferably an inorganic substance exhibiting superior thermal stability, workability, and mechanical strength. Examples of the inorganic skeleton material include oxides of titanium, silicon, aluminum, boron, germanium, lanthanum, magnesium, niobium, phosphorus, tantalum, tin, vanadium, and zirconium. Metal alkoxides of these materials are particularly preferable. The metal alkoxides can exhibit superior compatibility with the pore-forming material in the precursor film forming step.

Examples of the metal alkoxides include: tetraethoxytitanium, tetraisopropoxytitanium, tetramethoxytitanium, tetra-n-butoxytitanium, tetraethoxysilane, tetraisopropoxysilane, tetramethoxysilane, tetra-n-butoxysilane, triethoxyfluorosilane, triethoxysilane, triisopropoxyfluorosilane, trimethoxyfluorosilane, trimethoxysilane, tri-n-butoxyfluorosilane, tri-n-propoxyfluorosilane, trimethylmethoxysilane, trimethylethoxysilane, trimethylchlorosilane, phenyltriethoxysilane, phenyldiethoxychlorosilane, methyltrimethoxysilane, methyltriethoxysilane, ethyltriethoxysilane, dimethyldimethoxysilane, dimethyldiethoxysilane, trismethoxyethoxyvinylsilane, triethoxyaluminum, triisobutoxyaluminum, triisopropoxyaluminum, trimethoxyaluminum, tri-n-butoxyaluminum, tri-n-propoxyaluminum, tri-sec-butoxyaluminum, tri-tert-butoxyaluminum, triethoxyboron, triisobutoxyboron, triisopropoxyboron, trimethoxyboron, tri-n-butoxyboron, tri-sec-butoxyboron, tetraethoxygermanium, tetraisopropoxygermanium, tetramethoxygermanium, tetra-n-butoxygermanium, trismethoxyethoxylanthanum, bismethoxyethoxymagnesium, pentaethoxyniobium, pentaisopropoxyniobium, pentamethoxyniobium, penta-n-butoxyniobium, penta-n-propoxyniobium, triethylphosphate, triethylphosphite, triisopropoxyphosphate, triisopropoxyphosphite, trimethylphosphate, trimethylphosphite, tri-n-butylphosphate, tri-n-butylphosphite, tri-n-propylphosphate, tri-n-propylphosphite, pentaethoxytantalum, pentaisopropoxytantalum, pentamethoxytantalum, tetra-tert-butoxytin, tin acetate, triisopropoxy-n-butyltin, triethoxyvanadyl, tri-n-propoxyoxyvanadyl, vanadium trisacetylacetonate, tetraisopropoxyzirconium, tetra-n-butoxyzirconium, and tetra-tert-butoxyzirconium.

Among these alkoxides preferred are tetraisopropoxytitanium, tetra-n-butoxytitanium, tetraethoxysilane, tetraisopropoxysilane, tetramethoxysilane, tetra-n-butoxysilane, triisobutoxyaluminum, and triisopropoxyaluminum.

Among the above-listed metal alkoxide, preferred are inorganic substances mainly containing silica or silicon alkoxides, such as tetraethoxysilane and tetraisopropoxysilane. These silicon alkoxides achieve a porous film with a much lower dielectric constant.

The pore-forming material is preferably an organic substance capable of being easily dispersed in the skeleton material, and a surfactant is suitable as such an organic substance. An appropriate concentration of surfactant forms micelles, which are aggregates of surfactant molecules. The micelles are arranged to form a regular cylindrical or layered structure according to the concentration. Consequently, the skeleton material, which forms the skeleton around the micelles, has a regular structure. In other words, the micelles are formed in the skeleton. Thus, pore sources can be regularly placed in the skeleton. By introducing such a regular void structure, the mechanical strength of the resulting porous structure can be enhanced.

Nonionic or ionic surfactants may be used as the surfactant. The nonionic surfactants include ethylene oxide derivatives, propylene oxide derivatives, and their copolymers.

The ethylene oxide derivatives and propylene oxide derivatives include polyoxyethylene decyl ether, polyoxyethylene lauryl ether, polyoxyethylene cetyl ether, polyoxyethylene olein ether, polyoxyethylene coconut alcohol ether, polyoxyethylene refined coconut alcohol ether, polyoxyethylene 2-ethylhexyl ether, polyoxyethylene synthetic alcohol ether, polyoxyethylene sec-alcohol ether, polyoxyethylene tridecyl ether, polyoxyethylene isostearyl ether, polyoxyethylene long-chain alkyl ether, polyoxyethylene octylphenyl ether, polyoxyethylene nonylphenyl ether, polyoxyethylene dodecylphenyl ether, polyoxyethylene dinonylphenyl ether, polyoxyethylene styrenated phenyl ether, polyoxyethylene phenyl ether, polyoxyethylene benzyl ether, polyoxyethylene β-naphthyl ether, polyoxyethylene bisphenol A ether, polyoxyethylene bisphenol F ether, polyoxyethylene laurylamine, polyoxyethylene tallow amine, polyoxyethylene stearylamine, polyoxyethylene oleylamine, polyoxyethylene tallow propylenediamine, polyoxyethylene stearylpropylenediamine, polyoxyethylene N-cyclohexylamine, polyoxyethylene meta-xylenediamine, polyoxyethylene oleylamide, polyoxyethylene stearylamide, polyoxyethylene castor oil, polyoxyethylene hydrogenated castor oil, polyoxyethylene monolaurate, polyoxyethylene monostearate, polyoxyethylene monotallow oleate, polyoxyethylene monotolloil fatty acid monoester, polyoxyethylene distearate, polyoxyethylene rosin ester, polyoxyethylene wool grease ether, polyoxyethylene lanolin ether, polyoxyethylene lanolin alcohol ether, polyoxyethylene polyethylene glycol, polyoxyethylene glycerol ether, polyoxyethylene trimethylolpropane ether, polyoxyethylene sorbitol ether, polyoxyethylene pentaerythritol dioleate ether, polyoxyethylene sorbitan monostearate ether, polyoxyethylene sorbitan monooleate ether, polyoxyethylene polyoxypropylene glycol, polyoxyethylene polyoxypropylene 2-ethylhexyl ether, polyoxyethylene polyoxypropylene isodecyl ether, polyoxyethylene polyoxypropylene synthetic alcohol ether, polyoxyethylene polyoxypropylene tridecyl ether, polyoxyethylene polyoxypropylene nonylphenyl ether, polyoxyethylene polyoxypropylene styrenated phenyl ether, polyoxyethylene polyoxypropylene laurylamine, polyoxyethylene polyoxypropylene tallow amine, polyoxyethylene polyoxypropylene isodecyl ether, polyoxyethylene polyoxypropylene tridecyl ether, polyoxyethylene polyoxypropylene lauryl ether, polyoxyethylene polyoxypropylene stearyl ether, polyoxyethylene polyoxypropylene glyceryl ether, polyoxypropylene 2-ethylhexyl ether, polyoxypropylene synthetic alcohol ether, polyoxypropylene butyl ether, polyoxypropylene bisphenol A ether, polyoxypropylene styrenated phenyl ether, and polyoxypropylene meta-xylenediamine.

The copolymers of the ethylene oxide derivatives and propylene oxide derivatives include copolymers of the above-listed derivatives. The Pluronic series produced by BASF are commercially available copolymers. Examples of applicable Pluronic series include L31, L35, L42, L43, L44, L61, L62, L63, L64, L72, L81, L92, L101, L121, L122, P65, P75, P84, P85, P103, P104, P105, P123, F38, F68, F77, F87, F88, F98, F108, F127, 10R5, 10R8, 12R3, 17R1, 17R2, 17R4, 17R8, 22R4, 25R1, 25R2, 25R4, 25R5, 25R8, 31R1, 31R2, and 31R4. The above-listed surfactant may be used singly or in combination.

The ionic surfactant may be a quaternary alkylammonium salt with an alkyl group having a carbon number in the range of 8 to 24, such as CₙH₂ₙ₊₁(CH₃)₃N⁺M⁻, CₙH₂ₙ₊₁(C₂H₅)₂N⁺M⁻, CₙH₂ₙ₊ₐNH₂, and H₂N(CH₂)ₙNH₂, wherein M represents an anionic atom. Examples of the ionic surfactant include dodecanyltrimethylammonium chloride, tetradecanyltrimethylammonium chloride, hexadecyltrimethylammonium chloride, octadecanyltrimethylammonium chloride, dodecanyltrimethylammonium bromide, tetradecanyltrimethylammonium bromide, hexadecyltrimethylammonium bromide, octadecanyltrimethylammonium bromide, dodecanyltriethylammonium chloride, tetradecanyltriethylammonium chloride, hexadecyltriethylammonium chloride, octadecanyltriethylammonium chloride, dodecanyltriethylammonium bromide, tetradecanyltriethylammonium bromide, hexadecyltriethylammonium bromide, and octadecanyltriethylammonium bromide.

A so-called Gemini surfactant, such as CₙH₂ₙ₊₁X₂N⁺M⁻(CH₂)ₛN⁺M⁻X₂CₘH₂ₘ₊₁, which has a plurality of hydrophilic groups and hydrophobic groups in its molecule, may be used as the ionic surfactant, wherein m and n represent integers in the range of 5 to 20, and s represents an integer in the range of 1 to 10. In the structural formula, M represents a hydrogen atom or an anion easily forming a salt (for example, Cl⁻ or Br⁻); X represents a hydrogen atom or a lower alkyl group (for example, CH₃ or C₂H₅) . More specifically, such Gemini surfactants include C₁₂H₂₅(CH₃)₂N⁺Cl⁻(CH₂)₄N⁺Cl⁻(CH₃)₂C₁₂H₂₅, C₁₂H₂₅(CH₃)₂N⁺Br⁻(CH₂)₄N⁺Br⁻(CH₃)₂C₁₂H₂₅, C₁₆H₃₃(CH₃)₂N⁺Cl⁻(CH₂)₄N⁺Cl⁻(CH₃)₂C₁₆H₃₃, and C₁₆H₃₃(CH₃)₂N⁺Br⁻(CH₂)₄N⁺Br⁻(CH₃)₂C₁₆H₃₃ .

The supercritical fluid used for extracting the pore-forming material after the oxidation decomposition mainly contains carbon dioxide or an alkyl alcohol, such as methyl alcohol, ethyl alcohol, or propyl alcohol (the alkyl alcohol may be a simple alkyl alcohol or a mixture of at least two alkyl alcohols). In view of industrial production, a mixture of carbon dioxide and an alkyl alcohol is preferably used. Any of these supercritical fluids can be compatible with various types of material. The alkyl alcohol not only forms a supercritical fluid, but also promotes the extraction of the pore-forming material.

The capability of the supercritical fluid in extracting the pore-forming material largely depends on the density of the supercritical fluid. The density of the supercritical fluid varies depending on temperature or pressure, but, in practice, it is about 0.2 to 0.9 g/cm³. If the density is in this range, the molecular weight of the pore-forming material to be extracted is as low as about 1,500. Accordingly, in use of a supercritical fluid with such a practical density, the molecular weight of the pore-forming material after oxidation decomposition is preferably 1,500 or less.

The present invention will be further described in detail with reference to the following examples, but it is to be understood that the invention is not limited to the following examples.

### EXAMPLE

Uniformly blended were 1.9 g of tetraethoxysilane Si(C₂H₅O)₄ being the skeleton material, 2.578 g of Pluronic F127 (produced by BASF) being the pore-forming material, 8.846 g of ethanol, and 3.43 g of water. The mixture was stirred at 60° C. for about an hour to prepare a transparent, uniform, viscous solution. The solution was applied onto a substrate by spin coating and dried at 100° C. in air to form a precursor film of about 0.01 mm in thickness. At the same time, an electric furnace was prepared by introducing oxygen gas at a flow rate of 1 L/minute into the furnace under atmospheric pressure. The temperature inside the furnace was set at 130° C. The precursor film with the substrate was placed in the furnace. After the precursor film was allowed to stand at the same temperature for 30 minutes, the precursor film with the substrate was taken out of the furnace. The pore-forming material was thus decomposed by oxidation. While the molecular weight of the pore-forming material had been about 15,000 before the oxidation decomposition, the molecular weight was reduced to about 110 by the oxidation decomposition.

The molecular weight of the pore-forming material after the oxidation decomposition was estimated from the infrared absorbances before and after the oxidation decomposition as follows. FIG. 2, described later, is a graph showing the relationship between the wave number and the absorbance obtained by Fourier transform infrared spectroscopy (FTIR). Attention is focused on the intensities of the absorption bands around 2880 cm⁻¹, which are derived from the C—H bond, before and after the oxidation decomposition. The intensity of the absorbance was about 40% reduced by oxidation. F127 used as the pore-forming material is a block copolymer of polyethylene oxide and polypropylene oxide. The oxidation decomposition breaks the —C—O—C— bonds of the F127 and forms C═O bonds to destroy C—H bonds. F127 has about 340 —C—O—C— bonds in rough terms. Since it was estimated that 40% of the C—H bonds were destroyed, about 136 —C—O—C— bonds were probably broken. This means that the original molecules were divided into 136 smaller parts. Since the initial molecular weight was about 15,000, the molecular weight after the decomposition was estimated to be about 110. This molecular weight is much smaller than 1,500, which is the upper limit of molecular weight allowing supercritical extraction; hence, the decomposed molecules can be easily extracted with a supercritical fluid.

After the oxidation decomposition of the pore-forming material, the supercritical extraction was performed according to the following procedure.

The substrate having the precursor film was place in a high-pressure container, and then carbon dioxide of 80° C. was introduced into the high-pressure container. The internal pressure of the container was increased to 15 MPa by adjusting a regulator to create a supercritical state. The carbon dioxide supercritical fluid theoretically has a density of about 0.43 g/cm³. While carbon dioxide was introduced into the supercritical state at a flow rate of 10 mL/minute (at this flow rate, carbon dioxide is in a form of liquid), methanol acting as an extraction promoter was added at a rate of 1 mL/minute. Supercritical extraction was thus performed for 60 minutes. After the introduction of methanol was stopped, only carbon dioxide was introduced into the container at a flow rate of 10 mL/minute with the state held for 10 minutes, thereby discharging the methanol from the container. Then, the pressure of the high-pressure container was reduced and the substrate was taken out.

The substrate was coated with a transparent film. The film was observed through an electron microscope. As a result, it was confirmed that a regular structure having 10 nm pores had been formed.

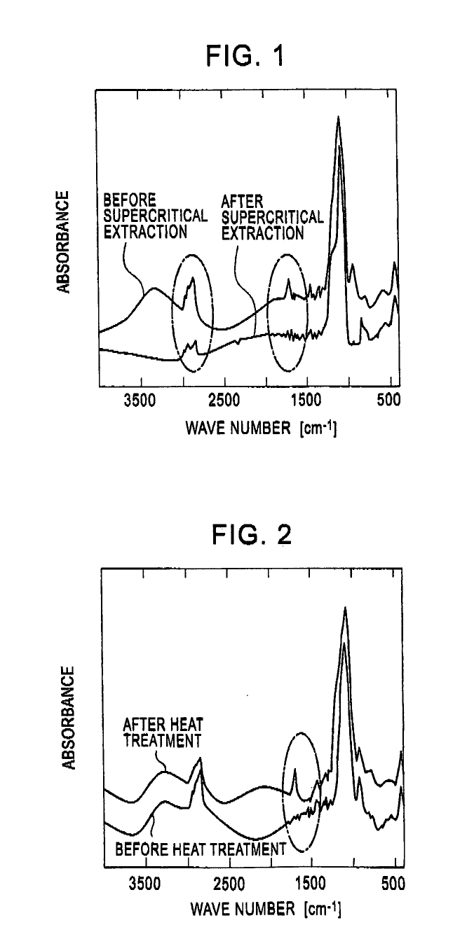

The resulting film was subjected to FTIR analysis. As a result, the bands around 2,880 cm⁻¹ derived from the C—H bond, which had been present before the supercritical extraction, disappeared after the supercritical extraction, as shown in FIG. 1. This confirms that Pluronic F127 was completely removed. Also, the bands around 1,725 cm⁻¹ derived from the C═O bond, which had been present before the supercritical extraction, disappeared after the supercritical extraction. This confirms that oxidized sections of Pluronic F127 were completely removed.

The changes of the film by heat treatment performed in an oxygen atmosphere were also analyzed by FTIR. The results are shown in FIG. 2. FIG. 2 shows that the bands around 1,725 cm⁻¹ derived from the C═O bond were not observed before the heat treatment in an oxygen atmosphere, while the bands around 1,725 cm⁻¹ appeared after the heat treatment. This confirms that Pluronic F127 was oxidized and decomposed by the heat treatment in the oxygen atmosphere.

The resulting film was provided with an Al electrode on the surface, and the capacitance of the film was measured to determine the relative dielectric constant of the film. As a result, the film had a relative dielectric constant of 1.5. This shows that extremely high-quality porous film was formed.

A comparative example was also performed on the precursor film. In the comparative example, the precursor film was heat treated in a nitrogen atmosphere at 130° C. under atmospheric pressure for 60 minutes. In the supercritical extraction, methanol acting as the extraction promoter was supplied over a period of 30 minutes. Other operations were performed in the same manner as in the above example. A porous film was thus formed.

The substrate was coated with a transparent film, but the film was dotted with droplet-like matter. The resulting film was observed through an electron microscope. As a result, no regular structure was found.

FTIR analysis showed that the bands around 2,880 cm⁻¹ remained even after the supercritical extraction; hence, Pluronic F127 could not be removed. The bands around 1,725 cm⁻¹ were not observed after the treatment in the nitrogen atmosphere; hence, the treatment in the nitrogen atmosphere did not decompose Pluronic F127.

The resulting film of the comparative example was subjected to a capacitance measurement to determine the relative dielectric constant of the film in the same manner as in the above example. As a result, the relative dielectric constant was 3. This means that the heat treatment in the nitrogen atmosphere cannot sufficiently remove the pore-forming material.

1. A method for forming a porous film, comprising:
the precursor film forming step of forming a precursor film containing a mixture of a skeleton material for forming a skeleton of the porous film and a pore-forming material for forming pores;
the decomposition step of decomposing the pore-forming material by oxidation in an oxidizing atmosphere; and
the extraction step of extracting the decomposed pore-forming material with a supercritical fluid.

2. The method according to claim 1, wherein the pore-forming material comprises an organic substance.

3. The method according to claim 2, wherein the organic substance is a surfactant.

4. The method according to claim 3, wherein the surfactant is a nonionic surfactant.

5. The method according to claim 3, wherein the decomposition step decomposes the surfactant in an oxidizing atmosphere containing an oxidizing gas at a temperature of 100 to 150° C.

6. The method according to claim 1, wherein the skeleton material comprises an inorganic substance.

7. The method according to claim 6, wherein the inorganic substance mainly contains silica.

8. The method according to claim 1, wherein the supercritical fluid mainly contains at least one of carbon dioxide and an alkyl alcohol.

9. A porous film formed by the method comprising: the precursor film forming step of forming a precursor film containing a mixture of a skeleton material for forming a skeleton of the porous film and a pore-forming material for forming pores, the decomposition step of decomposing the pore-forming material by oxidation in an oxidizing atmosphere; and the extraction step of extracting the decomposed pore-forming material with a supercritical fluid.
